(19) United States
(12) Patent Application Publication
(10) Pub. No.: US 2018/0307051 A1
(43) Pub. Date: Oct. 25, 2018

(54) LIGHTING APPARATUS FOR GENERATING STRUCTURED LIGHT

(71) Applicant: EVERREADY PRECISION IND. CORP., Kaohsiung City (TW)

(72) Inventors: JYH-LONG CHERN, Zhubei City (TW); CHIH-MING YEN, Taipei City (TW)

(21) Appl. No.: 16/010,937

(22) Filed: Jun. 18, 2018

Related U.S. Application Data
(63) Continuation-in-part of application No. 14/884,094, filed on Oct. 15, 2015.

(30) Foreign Application Priority Data
Aug. 28, 2015 (TW) 104128453

(51) Int. Cl. G02B 27/09; G02B 5/18; H01S 5/00

(52) U.S. Cl. CPC G02B 27/0944; H01S 5/005; G02B 27/0927; G02B 5/1819

(57) ABSTRACT

A lighting apparatus includes a laser source module, a diffractive optical module and a reflective module. The laser source module emits a laser beam and is operated in a transverse mode or a multi-transverse mode or a condition of multiple lasing modes to generate the laser beam of a light-beam mode pattern. The reflective module receives and reflects the laser beam of the light-beam mode pattern, and the diffractive optical module diffracts the reflecting laser beam to form a structure light. The diffractive optical module includes a diffractive structure having a distribution pattern of microstructure consistent with the light-beam mode pattern.

### CROSS REFERENCE TO RELATED APPLICATION

This application is a continuation-in-part of U.S. patent application Ser. No. 14/884,094, filed on Oct. 15, 2015, and entitled “LIGHTING APPARATUS WITH CORRESPONDING DIFFRACTIVE OPTICAL ELEMENT”, which claims the benefit of and priority to Taiwan Patent Application No. 104128452, now Taiwan Patent No. 1585467, all of which are herein incorporated by references.

### FIELD OF THE INVENTION

The present invention relates to a lighting apparatus, and more particularly to a lighting apparatus with a laser source operated in a transverse mode or a multi-transverse mode, or in a form of a more general description, i.e., multiple lasing modes

### BACKGROUND OF THE INVENTION

Generally, depending on a laser medium, the laser devices are divided into three types, i.e., a liquid laser device, a gas laser device and a solid laser device. The gas laser device such as a He—Ne laser is widely used. Recently, solid laser device including a semiconductor laser device or a laser diode (LD) has been used widely because of its compact size.

A Gaussian distribution profile and the corresponding light-beam mode pattern (denoted as 00) are shown in FIG. 1. Moreover, depending on the shape of the optical resonator, the light-beam mode pattern is similar to a circular beam with concentrated intensity in the center. Under this circumstance, the laser is said to be operated in a “00” mode as derived from the mathematical solutions of some differential equations based on a resonator consideration.

Shown in FIG. 2A, the laser device 100 includes a diffractive optical element (DOE) 11 disposed on a first surface 121 of a substrate 12 and arranged in front of a laser source 10. The substrate 12 is made of a transparent material. The laser source 10 emits a laser beam 10a that may be modulated by a collimating lens 14. Consequently, a parallel collimated beam 10b is outputted from the collimating lens 14. The collimated beam 10b is incident on, diffracted by the microstructures on the DOE 11 and then to form a structured light 13. The structured light 13 with a desired structured light pattern is projected to a specified distance or a specified space. In some cases, the collimating lens 14 may be removed, and the laser light is directly guided to the DOE 11 to produce the structured lighting pattern while the contrast of structured light may be poor.

In case that the diffractive optical element for a laser diode is employed, the diffractive optical element has to effectively cover the distribution range of the laser beam or the collimated beam on a plane that is perpendicular to a propagation direction. Shown in FIG. 2B, the two distributions of possible microstructures 110 on the diffractive optical element 11 are circular and rectangular to cover the irradiation of all incident laser beam.

FIGS. 2C and 2D are schematic side views illustrating the operations of two laser devices that are modified according to the concepts of the laser device of FIG. 2A. In the laser device 101 of FIG. 2C, the diffractive optical element 11 is disposed on a second surface 122 of the substrate 12. In the laser device 102 of FIG. 2D, the laser source 10 does not cooperate with the collimating lens. That is, the laser beam 10a from the laser source 10 is a dot beam. The arrangement of FIG. 2C can produce the structured light 13 same as the one of FIG. 2A, as well as FIG. 2D where the structured light 132 is outputted.

On the other hand, in case that the laser source (e.g., a laser diode) with coherence or partial coherence is operated in higher power, gain efficacy in optical resonator is continuously increased. Under this circumstance, the light-beam mode pattern is no longer the circular dot beam (i.e., in the Gaussian distribution). For example, various light-beam mode patterns of the transverse mode or the multi-transverse mode are shown in FIGS. 3A and 3B.

The light-beam mode patterns of the transverse mode or the multi-transverse mode are electromagnetic fields of laser beam that are measured on a plane perpendicular to the propagation direction. In case of optical resonator of a cylindrical shape, various light-beam mode patterns of the transverse mode or the multi-transverse mode are shown in FIG. 3A. In case of optical resonator of a rectangular shape, various light-beam mode patterns in the transverse mode or the multi-transverse mode are shown in FIG. 3B.

In FIG. 3A, the numeral 01* (or a circular mode 01*) indicates a ring-shaped pattern (or a donut pattern) where the center of the light-beam mode pattern is a hole without light pattern distribution. FIG. 4 schematically illustrates an amplitude distribution (or an intensity profile) of a laser beam corresponding to the ring-shaped light-beam mode pattern (or the circular mode 01*). Accordingly, it is found that the center hole of the ring-shaped pattern corresponds to a relative minimum intensity and the ring-shape pattern itself corresponds to a relative maximum intensity.

For the apparatus of projected structured light, it is important to use the laser beam with the lowest order, i.e., a Gaussian beam. In case that the laser source is operated in the transverse mode or the multi-transverse mode, a conventional diffractive optical element aforementioned cannot effectively control the beam diffraction and result in aprojected structured light pattern which is deformed and blurred, and even may have multiple ghost images. Under this circumstance, the desired structured light pattern cannot be acquired.

Therefore, it is important to overcome the drawbacks of the conventional technologies.

### SUMMARY OF THE INVENTION

Accordingly, a lighting apparatus with a diffractive optical element is provided. The corresponding diffractive optical element has a distribution of microstructure consistent with the light-beam mode pattern of a laser source operated in a transverse mode or a multi-transverse mode. In addition, the laser source in the transverse mode or the multi-transverse mode can well cooperate with the diffractive optical element.

In accordance with an aspect of the present invention, there is provided a lighting apparatus. The lighting apparatus includes a laser source module emitting a laser beam, wherein the laser beam has a light-beam mode pattern of a transverse mode, a multi-transverse mode or a condition of multiple lasing modes; a first reflective member receiving and reflecting the laser beam from the laser source module to form plural groups of first-reflecting laser beam; plural second reflective members arranged to respectively receive and reflect the groups of first-reflecting laser beam from the first reflective member to form plural groups of second-reflecting laser beam; and a diffractive optical module arranged to receive and diffract the groups of second-reflecting laser beam, wherein the diffractive optical module comprises plural portions of diffractive microstructure and each portion of diffractive microstructure is of a distribution pattern of microstructure consistent with the light-beam mode pattern of a transverse mode or a multi-transverse mode, and the groups of second-reflecting laser beam are diffracted to form plural groups of structured light.

In accordance with another aspect of the present invention, a lighting apparatus is provided to include a laser source module emitting a laser beam, wherein the laser beam has a light-beam mode pattern of a transverse mode or a multi-transverse mode; and a diffractive-reflective module receiving, diffracting and reflecting the laser beam from the laser source module to form a structured light, wherein the diffractive-reflective module comprises a diffractive microstructure having a distribution pattern of microstructure consistent with the light-beam mode pattern of a transverse mode or a multi-transverse mode.

In accordance with another aspect of the present invention, a lighting apparatus is provided to include a laser source module emitting a laser beam, wherein the laser beam has a light-beam mode pattern of a transverse mode, a multi-transverse mode or a condition of multiple lasing modes; a reflective member receiving and reflecting the laser beam from the laser source module to form a reflecting laser beam; and a diffractive optical element receiving and diffracting the reflecting laser beam to from a structured light, wherein the diffractive optical element comprises a diffractive microstructure having a distribution pattern of microstructure consistent with the light-beam mode pattern of a transverse mode or a multi-transverse mode.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates an amplitude distribution of a laser beam in a Gaussian distribution profile and the corresponding light-beam mode pattern;

FIG. 2A is a schematic side view illustrating the operations of a laser device with a diffractive optical element according to the conventional technology;

FIG. 2B schematically illustrates two possible microstructures formed on the diffractive optical element of FIG. 2A;

FIGS. 2C and 2D are schematic side views illustrating the operations of two laser devices that are modified according to the concepts of the laser device of FIG. 2A;

FIGS. 3A and 3B schematically illustrate various light-beam mode patterns in a transverse mode or a multi-transverse mode;

FIG. 4 schematically illustrates an amplitude distribution of a laser beam corresponding to the ring-shaped light-beam mode pattern (or the circular mode 01*);

FIG. 5 is a schematic functional block diagram illustrating a lighting apparatus according to an embodiment of the present invention;

FIG. 6A is a schematic side view illustrating the operations of a lighting apparatus according to a first embodiment of the present invention;

FIG. 6B schematically illustrates a first diffractive optical element and a first distribution pattern of microstructure of the diffractive optical module of the lighting apparatus;

FIG. 7 is a schematic side view illustrating the operations of a lighting apparatus according to a second embodiment of the present invention;

FIG. 8A is a schematic side view illustrating the operations of a lighting apparatus according to a third embodiment of the present invention;

FIG. 8B schematically illustrates a first diffractive optical element and a third distribution pattern of microstructure of the diffractive optical module of the lighting apparatus; and

FIG. 9 is a schematic side view illustrating the operations of a lighting apparatus according to a fourth embodiment of the present invention.

FIG. 10 is a schematic side view illustrating the operations of a lighting apparatus according to a fifth embodiment of the present invention.

FIG. 11 is a schematic side view illustrating the operations of a lighting apparatus according to a sixth embodiment of the present invention.

FIG. 12 is a schematic side view illustrating the operations of a lighting apparatus according to a seventh embodiment of the present invention.

FIG. 13 is a schematic side view illustrating the operations of a lighting apparatus according to an eighth embodiment of the present invention.

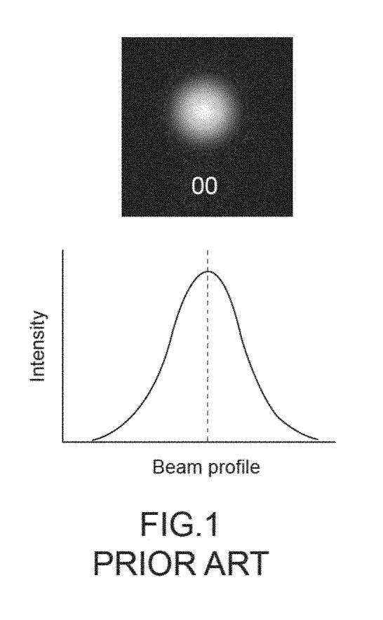

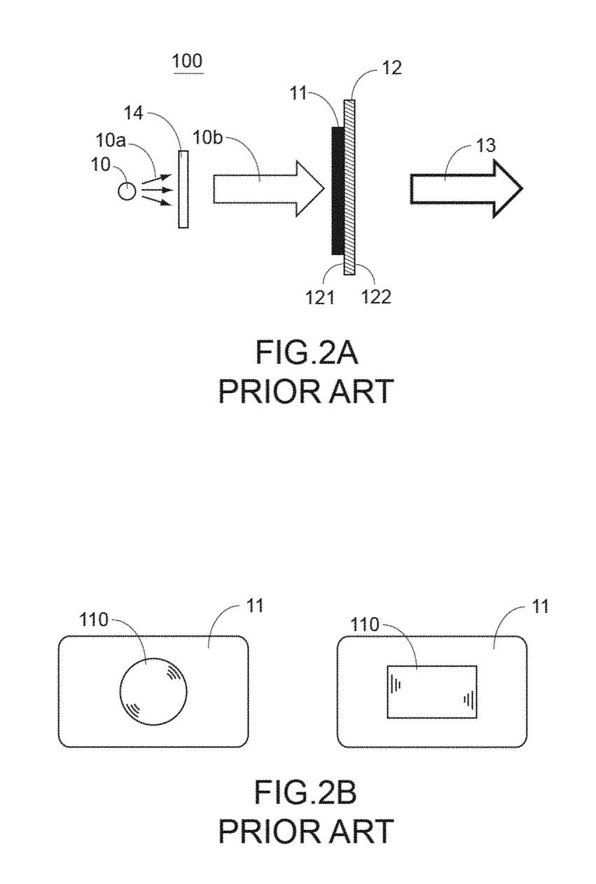

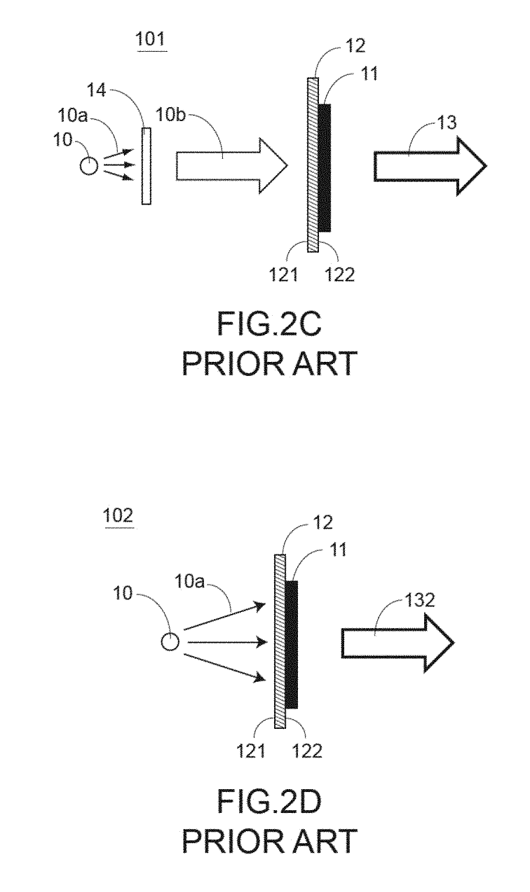

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. In the following embodiments and drawings, the elements irrelevant to the concepts of the present invention are omitted and not shown in order to clearly describe the technical features of the present invention. In the following embodiments, components that are relevant to each other or have similar function are designated by similar numeral references.

Shown in FIG. 5, the lighting apparatus 2 includes a casing 200, a laser source module 20, a diffractive optical module 201 and an operating module 202. The laser source module 20 and the diffractive optical module 201 are accommodated within the casing 200. The operating module 202 is disposed on the casing 200. A user may turn on the laser source module 20, turn off the laser source module 20 or adjust an operation mode of the laser source module 20 with the operating module 202. Optionally, the outer surface of the lighting apparatus 2, which is also the surface of the casing 200, is equipped with an elongated structure, a pillar structure or any other appropriate structure for allowing the user to hold it, or sheathing it around the finger, or facilitating the effective integration of the overall mechanism. Preferably, the overall effective height 203 (or the total thickness) of the casing 200 or the lighting apparatus 2 is equal to or smaller than 10 mm for a portable device application such as a mobile phone or a portable projector. However, the overall effective height 203 may be 35 mm or 25 mm in other applications. Although the dimension of lighting apparatus is small here, by precision fabrication technology, the casing 200 is still capable to have additional (mechanical, electric, magnetic, optical or the mixed) structures such that to the feedback light, stray light or unwanted light can be blocked out or be eliminated effectively and the unwanted light will not incident to DOE 201 or back to affect the laser source 20. Accordingly, the laser source module 20 with a compact size is preferred in the present invention. For example, a semiconductor laser such as a edge-emitting laser or a Vertical-Cavity Surface-Emitting Laser (VCSEL) is preferred used for the laser source module 20. Meanwhile, it is also possible by using additional structure within the casing 200 to pick up a small amount of the light from the laser 20 or the diffractive optical module 201 and pass to operating module 202 as for feedback control. Consequently, the lighting apparatus 2 can be effectively integrated into a handheld device. In accordance with a fabricating method, the laser source module 20 and the diffractive optical module 201 are fixed within the casing 200. Moreover, an end of the casing 200 is transparent or hollow, so that the generated light beam can be projected out. The operating module 202 is electrically connected with the laser source module 20. Moreover, the operating module 202 can transmit a control signal.

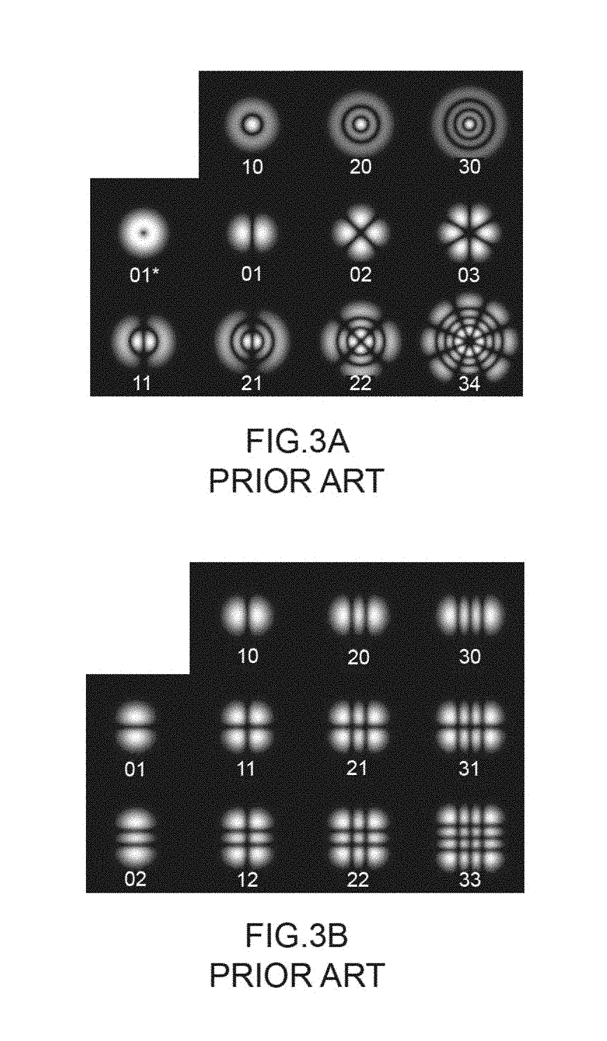

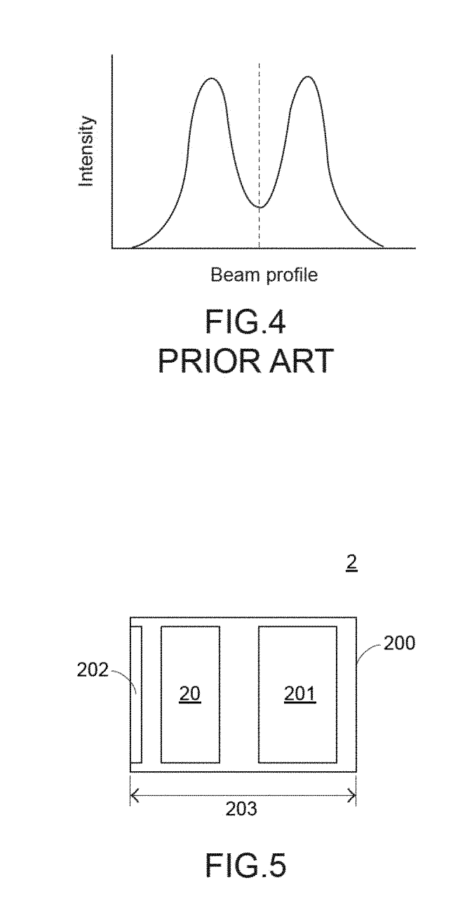

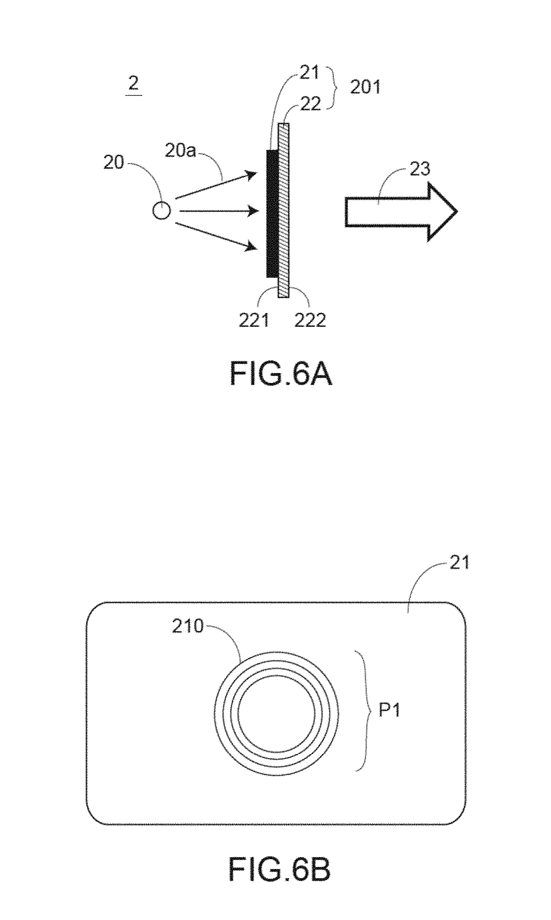

FIG. 6A is a schematic side view illustrating the operations of a lighting apparatus according to a first embodiment of the present invention. Shown in FIG. 6A, the laser source module 20 emits laser beam 20a of a dot beam. That is, the laser source module 20 does not cooperate with a collimating lens. In accordance with a feature of the present invention, the laser source of the laser source module 20 is operated in higher power of a transverse mode or a multi-transverse mode. That is, the light-beam mode pattern of the laser beam 20a is a non-fundamental mode pattern (i.e., a non-Gaussian distribution pattern). Various light-beam mode patterns of the transverse modes or the multi-transverse modes are shown in FIGS. 3A and 3B.

In this embodiment, a first light-beam mode pattern of the laser beam 20a is the numeral 01* pattern of FIG. 3A (or a circular mode 01* pattern), which is a ring-shaped pattern (or a donut pattern), or the center of the first light-beam mode pattern is a hole without light pattern distribution. Moreover, one or more semiconductor laser sources or laser diodes are provided for the laser source module 20. Alternatively, the laser source of the laser source module 20 may have coherence or partial coherence. In some other embodiments, the laser source module 20 further comprises a non-linear optical crystal or a liquid (or other substance) to produce other light beams with different wavelengths or in different spectra.

Referring to FIG. 6A again, the diffractive optical module 201 is arranged in front of the laser source module 20 or at a location that receives the laser beam 20a, so that the diffractive optical module 201 is irradiated by the laser beam 20a. Optionally, the casing 200 of FIG. 5 may accommodates the laser source module 20 and the diffractive optical module 201. In this embodiment, the diffractive optical module 201 comprises a substrate 22 and a first diffractive optical element 21. The substrate 22 has a first surface 221 and a second surface 222. The first diffractive optical element 21 is disposed on the first surface 221 of the substrate 22 that is located near the laser source module 20. The substrate 22 is made of a transparent material for passing through the laser beam 20a. Moreover, a first distribution pattern of microstructure P1 of the first diffractive optical element 21 is shown on the diffractive optical module 201 on the first surface 221 as FIG. 6B.

Next, the first distribution pattern of microstructure P1 on the first diffractive optical element 21 is consistent with the first light-beam mode pattern. The laser beam 20a passes through the first distribution pattern of microstructure P1 to be effectively diffracted. In particular, during the process of installing the laser source module 20 and the diffractive optical module 201 of the lighting apparatus 2, it is necessary to test the laser beam 20a from the laser source module 20 in order to realize the type of the light-beam mode pattern. That is, it is necessary to recognize the type of the light-beam mode pattern of the transverse mode or the multi-transverse mode. The first distribution pattern of microstructure P1 on the first diffractive optical element 21 may be determined according to the recognized type of the light-beam mode pattern.

As shown in FIG. 6B, plural first microstructures 210 are formed on the first diffractive optical element 21 to have the first distribution pattern of microstructure P1. In this embodiment, the first light-beam mode pattern of the laser beam 20a is set as the circular mode 01* pattern. Consequently, the plural first microstructures 210 are distributed according to the distribution of the circular mode 01* pattern (i.e., the light pattern distribution or the intensity distribution). In other words, the plural first microstructures 210 are formed on the first diffractive optical element 21 in a ring-shaped arrangement. In this embodiment, the first distribution pattern of microstructure P1 is constituted by all of the plural first microstructures 210.

Next, the laser beam 20a of the first light-beam mode pattern is incident onto the location of the first microstructures 210 of the first diffractive optical element 21, and the area of the laser beam 20a onto the first diffractive optical element 21 is smaller than or equal to the area of the first microstructures 210 of the first diffractive optical element 21. Consequently, when the laser beam 20a is irradiated on the first diffractive optical element 21 to be effectively diffracted. That is, the margin of the first distribution pattern of microstructure P1 covers and is consistent with the laser beam 20a of the first light-beam mode pattern. Consequently, any part of the first light-beam mode pattern for the laser beam 20a is not beyond or outside the first distribution pattern of microstructure P1. After the laser beam 20a is diffracted, a first structured light 23 with a first structured light pattern is generated (see FIG. 6A).

Referring to FIG. 6B again, the plural first microstructures 210 are symmetrically distributed to be consistent with the laser beam 20a of the light-beam mode pattern of symmetrical distribution. That is, the upper part and the lower part, the left part and the right part and the oblique parts are symmetric to each other with respect to the center of the light-beam mode pattern. However, in some situations, the generated light-beam mode pattern from a laser source is not in the ideal symmetry as the light-beam mode patterns of FIG. 3A or FIG. 3B because the material of inner structure of the lighting apparatus is not uniform or tiny dust exists or the laser source is operated at higher power. Under this circumstance, the generated light-beam mode pattern is asymmetrically distributed, or the generated light-beam mode pattern is a combination of several light-beam mode patterns in different modes. Consequently, in case that the first light-beam mode pattern is asymmetric, the corresponding microstructures are asymmetrically distributed.

It is noted that numerous modifications and alterations may be made while retaining the teachings of first embodiment. For example, in another embodiment, the first diffractive optical element 21 is disposed on the second surface 222 of the substrate 22. Since the substrate 22 is transparent, the diffracted result or the structured light pattern is not obviously distinguished from the first embodiment. Moreover, since the area of the first light-beam mode pattern on the first diffractive optical element 21 is smaller than the area of the first distribution pattern of microstructure P1, the range of the plural first microstructures can be larger than that of FIG. 6B or the number of the plural first microstructures can be more than that of FIG. 6B. That is, the portion of the first diffractive optical element 21 where the laser beam 20a of the light-beam mode pattern is irradiated should contain microstructures, and portions of the microstructures are possibly not irradiated by the light-beam mode pattern. Under this circumstance, the first distribution pattern of microstructure is constituted by portions of the plural first microstructures.

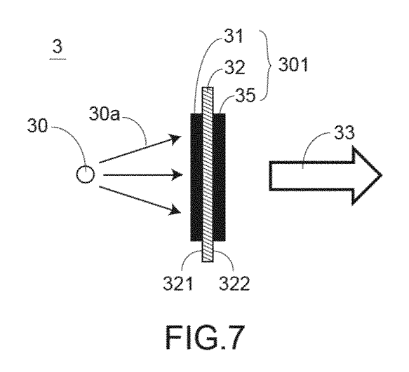

Hereinafter, a lighting apparatus according to a second embodiment will be described. FIG. 7 is a schematic side view illustrating the operations of a lighting apparatus according to a second embodiment of the present invention. Compared to the first embodiment in FIG. 6A, the diffractive optical module 301 of the lighting apparatus 3 further includes a second diffractive optical element 35 disposed on the second surface 322 of the substrate 32. Similarly, plural second microstructures (not shown) are formed on the second diffractive optical element 35 to form second distribution pattern of microstructure. The second distribution pattern of microstructure for the second diffractive optical element 35 is correlated with the first structured light pattern that is generated by passing the laser beam through the first diffractive optical element 31.

As mentioned in the first embodiment, the first structured light 23 is generated after the laser beam 20a passes through the first diffractive optical element 21. In case that the first structured light 23 passes through another diffractive optical element (e.g., the second diffractive optical element 35 of FIG. 7), another diffraction process occurs. The location of the first structured light incident onto the second diffractive optical element 35 correspond to the location of the second distribution pattern of microstructure of the second diffractive optical element 35, and the area of the first structured light incident onto the second diffractive optical element 35 is smaller than or equal to the area of the second distribution pattern of microstructure of the second diffractive optical element 35. Moreover, the second distribution pattern of microstructure of the second diffractive optical element 35 may be identical to or different from the first distribution pattern of microstructure of the first diffractive optical element 31. Next, a second structured light 33 with a second structured light pattern is generated. Accordingly, architecture aforementioned is used to generate a specified structured light pattern and re-modulate the light beam shape of the corresponding light beam.

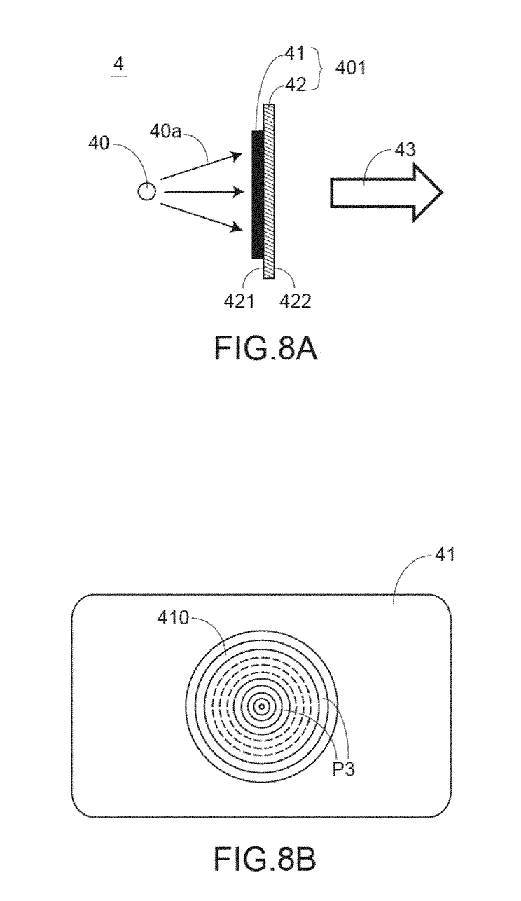

FIG. 8A is a schematic side view illustrating the operations of a lighting apparatus according to a third embodiment of the present invention. FIG. 8B schematically illustrates the first diffractive optical element 41 and a third distribution pattern of microstructure P3. In comparison with the first embodiment, the first diffractive optical element 41 of the third embodiment is divided into two parts.

As mentioned above, the user may adjust the operation mode of at least one laser sources (e.g., adjust the output power or modulate the length or other scale feature of the optical resonator) in order to change the light-beam mode pattern of the transverse mode or the multi-transverse mode. In some other embodiments, the laser source module further include an optical lens group (not shown). By adjusting the relative distance between the optical lens group and the diffractive optical module, the light-beam mode pattern is correspondingly adjusted.

In the third embodiment, a second light-beam mode pattern of the laser beam 40a from the laser source module 40 is the numeral 10 pattern of FIG. 3A (also referred as a circular mode 10 pattern) to have two parts including a ring-shaped pattern with a light pattern distribution in the center. The third distribution pattern of microstructure P3 on the first diffractive optical element 41 is consistent with the second light-beam mode pattern the laser beam 40a.

As shown in FIG. 8B, the third distribution pattern of microstructure P3 is constituted by portions of plural first microstructures 410. In particular, as shown in FIG. 8B, the third distribution pattern of microstructure P3 contains the microstructures 410 in the middle region and the microstructures 410 in the non-dotted region (i.e., the region indicated by solid lines). That is, the plural first microstructures 410 are divided into two parts according to the distribution of the circular mode 10 pattern (i.e., the light pattern distribution or the intensity distribution) and further according to distribution of other mode pattern (e.g., the circular mode 01* pattern).

For example, provided that the laser beam of the first light-beam mode pattern (i.e., the circular mode 01* pattern) is changed to the one of the second light-beam mode pattern (i.e., the circular mode 10 pattern), the irradiated range or location on the diffractive optical element 41 is correspondingly changed. For example, as shown in FIG. 8B, the irradiated range or location is changed from the microstructures 410 of the dotted region to the microstructures 410 of the solid region.

In other words, a portion of the first microstructures 410 constitute the first distribution pattern of microstructure P1 of FIG. 6B, and another portion of the first microstructures 410 constitute the third distribution pattern of microstructure P3. Depending to the distribution of the light-beam mode pattern, the portion of the first microstructures 410 constituting the first distribution pattern of microstructure P1 and the portion of the first microstructures 410 constituting the third distribution pattern of microstructure P3 may be partially overlapped with each other. Consequently, in the third embodiment, the lighting apparatus 4 can effectively utilize light-beam mode patterns in various modes.

Similarly, the location of the laser beam of second light-beam mode pattern incident onto the first diffractive optical element 41 is consistent with the location of the third distribution pattern of microstructure P3. The area of the laser beam of the second light-beam mode pattern incident onto the first diffractive optical element 41 is smaller than or equal to the area of the third distribution pattern of microstructure P3. After the laser beam 40a passes through the first diffractive optical element 41, a third structured light 43 with a third structured light pattern is generated showed in FIG. 8A.

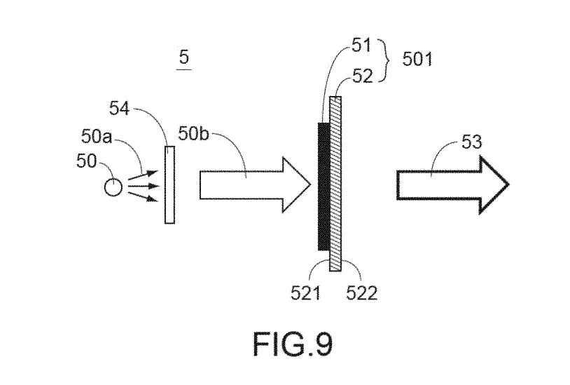

FIG. 9 shows a fourth embodiment. In comparison with the first embodiment, the lighting apparatus 5 of this embodiment further includes a collimating optical element 54 arranged in front of the laser source module 50. The collimating optical element 54 is configured to adjust the laser beam 50a to generate collimated beams 50b. However, the collimated beams 50b are still of the light-beam mode pattern of the laser beam 50a (e.g., the first light-beam mode pattern corresponding to the circular mode 01* pattern).

Referring to FIG. 9 continuously, the collimated beams 50b are diffracted by the first diffractive optical element 51 of the diffractive optical module 501. The designs of forming the first distribution pattern of microstructure or the plural first microstructures on the first diffractive optical element 51 are similar to those of the first embodiment. In particular, due to the collimating adjustment of the collimating optical element 54, the collimated beam 50b has smaller divergence than the laser beam 50a or is closer to the parallel beam. Consequently, when the collimated beam 50b is irradiated on the first diffractive optical element 51, the distribution range is smaller than that of the first embodiment. Then a first structured light 53 having a similar or identical result to the first embodiment is generated.

Similarly, the collimating optical element 54 can be applied to the lighting apparatus of the second embodiment or the third embodiment, or applied to the variant examples of the first embodiment, the second embodiment or the third embodiment. Under this circumstance, the generated light-beam mode pattern also has the similar or identical result.

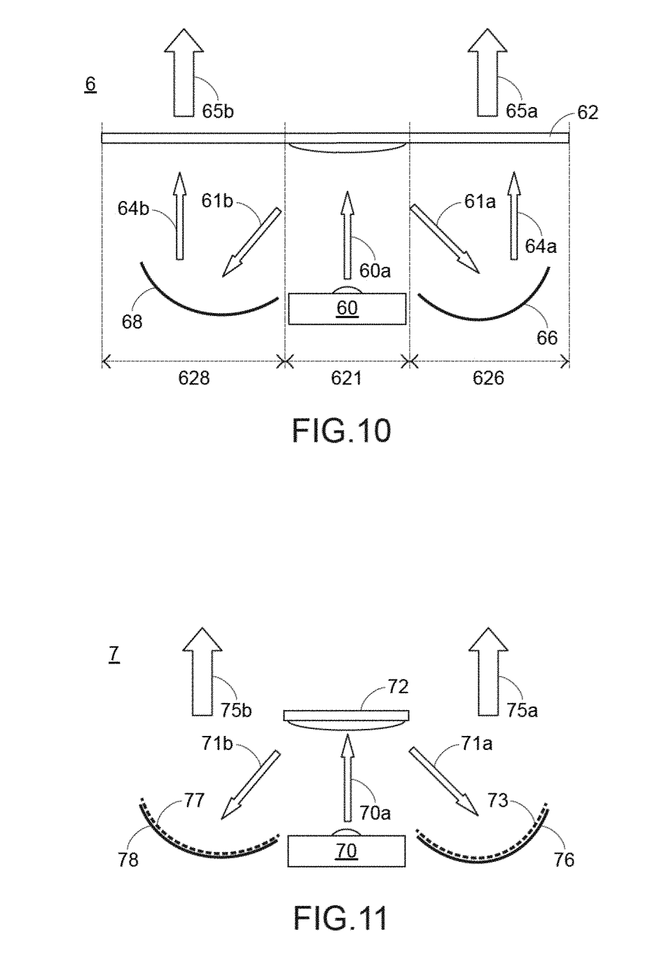

Shown in FIG. 10, a fifth lighting apparatus 6 includes a laser source module 60, a diffractive-reflective optical module 62 and plural reflective members 66 and 68. In the fifth embodiment, the laser source module 60 including a laser diode is arranged between the two reflective members 66, 68 and irradiates a laser beam 60a with two modes, i.e. TEM10. In the case of multiple lasing modes as they exhibited in the laser source module 60, the reflective member embedded on the plate of the diffractive-reflective optical module 62 can separate the laser beam 60a to be individual lasing modes 61a and 61b. The diffractive-reflective optical module 62 in front of the laser source module 60, the reflective member 66 and the reflective member 68 may include three portions: a reflective portion 621 and two diffractive portions 626, 628. Next, the reflective portion 621 of the diffractive-reflective optical module 62 is right in front of the laser source module 60. The reflective portion 621 receives and reflects the incident laser beam 60a to split two groups of first-reflecting laser beam 61a, 61b. The two groups of first-reflecting laser beam 61a, 61b respectively travel towards the directions where the reflective member 66 and the reflective member 68 are positioned. Besides, the diffractive portions 626 of the diffractive-reflective optical module 62 is right in front of the reflective member 66, and the diffractive portion 628 is right in front of the reflective member 68. For example but not limited to, the reflective portion 621, the reflective member 66, or the reflective member 68 may be a reflective film on a suitable substrate, a reflective structure formed on the suitable substrate, or reflective mirror, or others. Next, the groups of first-reflecting laser beam 61a, 61b respectively reach to and are guided by the reflective members 66, 68 to form the groups of second-reflecting laser beam 64a, 64b, respectively. The groups of second-reflecting laser beam 64a, 64b are then incident onto the diffractive portions 626, 628 of the diffractive-reflective optical module 62 to be diffracted for forming two groups of structured light 65a, 65b. Similarly, the distribution patterns of microstructure of the diffractive portions 626, 628 are consistent with the laser beam mode pattern of the laser beam 60a.

FIG. 11 is a schematic side view illustrating the operations of a lighting apparatus according to a sixth embodiment of the present invention. A sixth lighting apparatus 7 includes a laser source module 70, a reflective member 72 and plural diffractive-reflective optical modules. In the sixth embodiment, the laser source module 70 including a laser diode is arranged between the two diffractive-reflective optical modules and irradiates a laser beam 70a. In the case of multiple lasing modes which were emitted from the laser source module 70, the reflective member 72 can separate the lasing mode in two groups, i.e., laser beams 71a and 71b.) The reflective member 72 in right front of the laser source module 70 receives and reflects the incident laser beam 70a to split two groups of reflecting laser beam 71a, 71b. The groups of reflecting laser beam 71a, 71b are reflected back forwards the directions where the two diffractive-reflective optical modules are located. Next, one of diffractive-reflective optical module includes a diffractive optical element 73 and a reflective optical element 76, and the other one includes a diffractive optical element 77 and a reflective optical element 78. The reflective optical element or the reflective member 72 may be a reflective film on a suitable substrate, a reflective structure formed on the suitable substrate, or reflective mirror, or others. Next, the group of reflecting laser beam 71a is diffracted by the diffractive optical element 73 and reflected by the reflective optical element 76 to form a group of structured light 75a. Similarly, the group of reflecting laser beam 71b is diffracted by the diffractive optical element 77 and reflected by the reflective optical element 78 to form a group of structured light 75b. It is noted that the numbers of the diffractive-reflective optical modules may be designed according to the numbers of split groups of the reflecting laser beam. Similarly, the distribution patterns of microstructure of the diffractive optical elements 73, 77 are consistent with the laser beam mode pattern of the laser beam 70a.

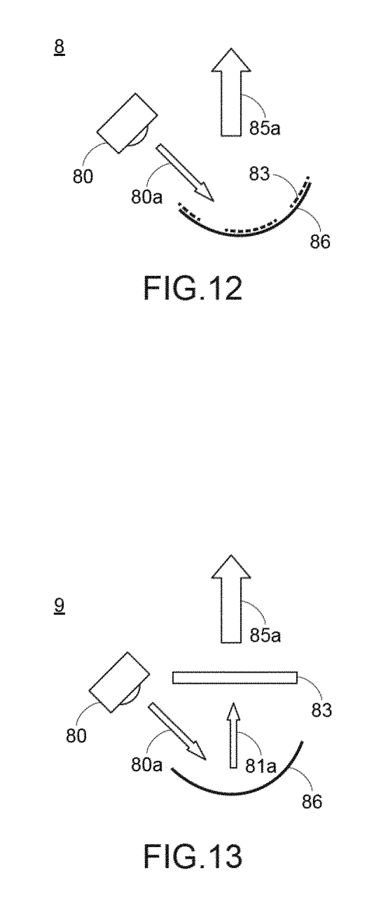

FIG. 12 is a schematic side view illustrating the operations of a lighting apparatus according to a seventh embodiment of the present invention. A seventh lighting apparatus 8 includes a laser source module 80 and a diffractive-reflective optical module including a diffractive optical element 83 and a reflective optical element 86. The diffractive-reflective optical module including a diffractive optical element 83 and a reflective element 86 may be arranged off-axis in front of the laser source module 80 to receive an incident laser beam 80a from the laser source module 80. The laser beam 80a is diffracted by the diffractive optical element 83 and reflected by the reflective element 86 to form a structured light 85a. However, because the laser beam 80a is tilted incident onto the diffractive-reflective optical module including the diffractive optical element 83 and the reflective optical element 86, the reflective element 86 necessitates to be asymmetric. In this embodiment, the reflective element 86 is a reflective base substrate and the diffractive optical element 83 includes microstructures formed on the reflective base substrate. In this embodiment, when the laser beam 80a is with multiple lasing mode, the corresponding diffractive optical element 83 and reflective element 86 are segmented, i.e., the elements are in a form of multiple sections, such that the separated modes in the laser beam profile can be matched accordingly. In other words, for another simple and straightforward embodiment, once the laser beam 80a is a Gaussian beam, the diffractive optical element 83 and the reflective base 86 are generally asymmetrical.

FIG. 13 is a schematic side view illustrating the operations of a lighting apparatus according to an eighth embodiment of the present invention. Compared to the seventh embodiment, for the eighth lighting apparatus 9, the diffractive optical element 83 is not integrated with the reflective element 86 and arranged at a position to receive the reflecting laser beam 81a from the reflective element 86. It is understood that the reflecting laser beam 81a is derived from the laser beam 80a to be reflected by the reflective element 86. In this embodiment, the distribution pattern of microstructure of the diffractive optical element 83 is consistent with the laser beam mode pattern of the laser beam 81a. In this embodiment, when the laser beam 80a is with multiple lasing mode, the corresponding diffractive element 83 and reflective element 86 are segmented, i.e., the elements are in a form of multiple sections, such that the separated modes in the laser beam profile can be matched accordingly. In other words, for another simple and straightforward embodiment, once the laser beam 80a is a Gaussian beam, the reflective base 86 are generally asymmetrical, but the diffractive optical element 83 will be simple.

Accordingly, with the arrangement of reflective materials, structures, films, or modules, the lighting apparatus may have more compact sizes, higher beam quality, i.e., with less noise, and a good control of beam shape. From the above descriptions, the present invention provides a lighting apparatus with a corresponding diffractive optical element. The corresponding diffractive optical element is selected according to the light-beam mode pattern of the used laser source. By means of the architecture, the laser source (especially the laser source operated in a transverse mode or a multi-transverse mode) can be effectively utilized. Consequently, the desired structured light pattern can be generated by the diffraction technology. In addition, the laser source in the transverse mode or the multi-transverse mode can well cooperate with the diffractive optical element.

Consequently, the lighting apparatus of the present invention is capable of achieving the purposes of the present invention while eliminating the drawbacks of the conventional technologies.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A lighting apparatus, comprising:
a laser source module emitting a laser beam, wherein the laser beam has a light-beam mode pattern of a transverse mode, a multi-transverse mode, or a condition of multiple lasing modes;
a first reflective member receiving and reflecting the laser beam from the laser source module to form plural groups of first-reflecting laser beam;
plural second reflective members arranged to respectively receive and reflect the groups of first-reflecting laser beam from the first reflective member to form plural groups of second-reflecting laser beam; and
a diffractive optical module arranged to receive and diffract the groups of second-reflecting laser beam, wherein the diffractive optical module comprises plural portions of diffractive microstructure and each portion of diffractive microstructure is of a distribution pattern of microstructure consistent with the light-beam mode pattern of a transverse mode or a multi-transverse mode, and the groups of second-reflecting laser beam are diffracted to form plural groups of structured light.

2. The lighting apparatus according to claim 1, wherein the first reflective member is integrated with the portions of diffractive microstructure and located among the portions of diffractive microstructure.

3. The lighting apparatus according to claim 2, wherein the first reflective member and the portions of diffractive microstructure are arranged in front of the laser source module, and the first reflective member is right in front of the laser source module.

4. The lighting apparatus according to claim 1, wherein the second reflective members are integrated with the portions of diffractive microstructure.

5. The lighting apparatus according to claim 4, wherein the laser source module is located among the second reflective members and the portions of diffractive microstructure.

6. The lighting apparatus according to claim 1, wherein the laser source module comprises an edge-emitting laser, a vertical-cavity-surface-emitting laser or a laser diode emitting the laser beam.

7. The lighting apparatus according to claim 1, wherein the diffractive optical module comprises a diffractive optical element with the portions of diffractive microstructure.

8. A lighting apparatus, comprising:
a laser source module emitting a laser beam, wherein the laser beam has a light-beam mode pattern of a transverse mode or a multi-transverse mode; and
a diffractive-reflective module receiving, diffracting and reflecting the laser beam from the laser source module to form a structured light, wherein the diffractive-reflective module comprises a diffractive microstructure having a distribution pattern of microstructure consistent with the light-beam mode pattern of a transverse mode, a multi-transverse mode, or a condition which has multiple lasing modes

9. The lighting apparatus according to claim 8, wherein the laser source module comprises an edge-emitting laser, a vertical-cavity-surface-emitting laser or a laser diode emitting the laser beam.

10. The lighting apparatus according to claim 8, wherein the diffractive-reflective module comprises a diffractive optical element with the diffractive microstructure.

11. The lighting apparatus according to claim 8, wherein the diffractive-reflective module comprises a reflective base substrate and the diffractive microstructure formed on the reflective base substrate.

12. A lighting apparatus, comprising:
a laser source module emitting a laser beam, wherein the laser beam has a light-beam mode pattern of a transverse mode, a multi-transverse mode, or a condition of multiple lasing modes;
a reflective member receiving and reflecting the laser beam from the laser source module to form a reflecting laser beam; and
a diffractive optical element receiving and diffracting the reflecting laser beam to from a structured light, wherein the diffractive optical element comprises a diffractive microstructure having a distribution pattern of microstructure consistent with the light-beam mode pattern of a transverse mode or a multi-transverse mode.

13. The lighting apparatus according to claim 12, wherein the laser source module comprises an edge-emitting laser, a vertical-cavity-surface-emitting laser or a laser diode emitting the laser beam.
